(19) United States
(12) Patent Application Publication
(10) Pub. No.: US 2012/0169183 A1
(43) Pub. Date: Jul. 5, 2012

(54) CERAMIC COMPOSITION FOR PIEZOELECTRIC ACTUATOR AND METHOD OF MANUFACTURING THE SAME, AND PIEZOELECTRIC ACTUATOR MANUFACTURED BY USING THE SAME

(75) Inventors: Boum Seock Kim, Suwon (KR); Seung Gyo Jeong, Hwaseong (KR); Eun Tae Park, Yongin (KR)

(73) Assignee: Samsung Electro-Mechanics Co., Ltd.

(21) Appl. No.: 13/335,161

(22) Filed: Dec. 22, 2011

(30) Foreign Application Priority Data
Dec. 30, 2010 (KR) 10-2010-0139022

(51) Int. Cl. H01L 41/047; B22F 7/02; C04B 35/01; H01L 41/187; H01L 41/04

(52) U.S. Cl. 310/363; 252/62.9 PZ; 310/365; 264/104; 419/6

(57) ABSTRACT

There are provided a ceramic composition for a piezoelectric actuator allowing for low-temperature sintering and a method of manufacturing the same, and a piezoelectric actuator. A Cuo powder and an MnO powder as an sintring additive are added to a PZT-PZN piezoelectric ceramic powder to allow low-temperature sintering at a temperature of 950° C. or lower, and the usage of high-priced palladium (Pd) used as materials for high-temperature inner electrodes is decreased due to lowering of the sintering temperature, and thereby to achieve cost reduction.

### CROSS-REFERENCE TO RELATED APPLICATIONS

This application claims the priority of Korean Patent Application No. 10-2010-0139022 filed on Dec. 30, 2010, in the Korean Intellectual Property Office, the disclosure of which is incorporated herein by reference.

### BACKGROUND OF THE INVENTION

1. Field of the Invention

The present invention relates to a ceramic composition for a piezoelectric actuator and a method of manufacturing the same, and a piezoelectric actuator manufactured by using the same, and more particularly, to a ceramic composition for a piezoelectric actuator allowing for low-temperature sintering and a method of manufacturing the same, and a piezoelectric actuator manufactured by using the same.

2. Description of the Related Art

Recently, a piezoelectric actuator controlling minute displacements or vibrations has been widely used with the development of precision machinery and of the information technology industry. The piezoelectric actuator has advantages, in that the miniaturization and precise control thereof are possible and, in comparison with a mechanical-type driving device, response speed is fast.

The piezoelectric actuator converts electrical energy into mechanical energy by using piezoelectric ceramics. A multilayer type piezoelectric actuator is formed by laminating piezoelectric actuators in order to obtain a high level of displacement.

The displacement of each disc in a piezoelectric actuator may be very small, but the discs may be laminated to generate a high level of displacement in the laminate type piezoelectric actuator.

In the multilayer type piezoelectric actuator, the thickness of each disc layer is formed to be relatively thin, and electrodes are formed in parallel inside each disc in order to lower working voltage, and thus, a high-strength electrical field can be generated.

In order to embody the structure of the multilayer type piezoelectric actuator, in which electrode layers and piezoelectric materials are formed in multiple layers, interfaces between the electrode layers and the piezoelectric materials need to be stably maintained, and the electrode layers and the piezoelectric materials need to be co-fired during processing.

For this co-firing, the melting point of an electrode needs to be higher than the firing temperature of materials. Herein, silver (Ag) and palladium (Pd) electrode materials containing a relatively expensive palladium element capable of maintaining the properties thereof, even at temperatures above the firing temperature of general piezoelectric materials, that is, 1100° C., are used in the electrodes.

As the piezoelectric materials used in the multilayer type piezoelectric actuator, PZT (PbZrₓTi₁₋ₓ, 0₃, 0<x<1) base materials are used, and the firing temperature thereof is 1100 to 1250° C., which is very high. Therefore, since electrode materials capable of withstanding this firing temperature should be used in inner electrodes between laminated PZT materials, electrode materials containing high levels of palladium, which is a relatively expensive electrode materials, have been used. However, the price of palladium has increased considerably as the worldwide usage thereof has increased.

### SUMMARY OF THE INVENTION

An aspect of the present invention provides a ceramic composition for a piezoelectric actuator allowing for low-temperature sintering and a method of manufacturing the same, and a piezoelectric actuator manufactured by using the same.

According to an aspect of the present invention, there is provided a ceramic composition for a piezoelectric actuator, including: a piezoelectric ceramic powder having a compositional formula of (1-x)Pb(Zr_{(1-y)}Ti_{y})O₃-xPb(Zn_{1/3}Nb_{2/3})O₃, where x is 0.2 to 0.4 and y is 0.4 to 0.7; and a CuO powder.

The ceramic composition may further include an MnO powder.

The CuO powder may have a content of 0.01 to 5 mol %.

The MnO powder may have a content of 0.01 to 5 mol %.

According to another aspect of the present invention, there is provided a method of manufacturing a ceramic composition for a piezoelectric actuator, the method including: preparing a ceramic mixture having a compositional formula of (1-x)Pb(Zr_{(1-y)}Ti_{y})O₃-xPb(Zn_{1/3}Nb_{2/3})O₃, by weighing raw materials such that x is 0.2 to 0.4 and y is 0.4 to 0.7 in the compositional formula; calcining the ceramic mixture to prepare a piezoelectric ceramic powder having a compositional formula of (1-x)Pb(Zr_{(1-y)}Ti_{y})O₃-xPb(Zn_{1/3}Nb_{2/3})O₃, where x is 0.2 to 0.4 and y is 0.4 to 0.7; and adding a CuO powder to the piezoelectric ceramic powder.

The raw materials may be PbO, ZrO₂, TiO₂, ZnO and Nb₂O₅.

The method may further include adding an MnO powder to the piezoelectric ceramic powder, after the adding of the CuO powder to the piezoelectric ceramic powder.

According to another aspect of the present invention, there is provided a piezoelectric actuator, including: one or more piezoelectric layers each including a ceramic composition containing a piezoelectric ceramic powder having a compositional formula of (1-x)Pb(Zr_{(1-y)}Ti_{y})O₃-xPb(Zn_{1/3}Nb_{2/3})O₃, where x is 0.2 to 0.4 and y is 0.4 to 0.7, and a CuO powder; and electrode layers each formed on at least one of an upper surface and a lower surface of the piezoelectric layer.

The piezoelectric layer may further include an MnO powder.

The electrode layer may be formed of a palladium (Pd)-silver (Ag) alloy.

The palladium (Pd)-silver (Ag) alloy may have a palladium content of 10 wt %.

The electrode layer may be formed of silver (Ag).

According to another aspect of the present invention, there is provided a method of manufacturing a piezoelectric actuator, the method including: preparing a ceramic mixture having a compositional formula of (1-x)Pb(Zr_{(1-y)}Ti_{y})O₃-xPb(Zn_{1/3}Nb_{2/3})O₃, by weighing raw materials such that x is 0.2 to 0.4 and y is 0.4 to 0.7 in the compositional formula; calcining the ceramic mixture to prepare a piezoelectric ceramic powder having a compositional formula of (1-x)Pb(Zr_{(1-y)}Ti_{y})O₃-xPb(Zn_{1/3}Nb_{2/3})O₃, where x is 0.2 to 0.4 and y is 0.4 to 0.7; adding a CuO powder to the piezoelectric ceramic powder; forming piezoelectric layers of the ceramic composition including the piezoelectric ceramic powder;

forming electrode layers each on at least one of an upper surface and a lower surface of each of the piezoelectric layers to form a laminate body; and firing the laminate body at a temperature of 950° C. or lower.

The raw materials may be PbO, ZrO₂, TiO₂, ZnO and Nb₂O₅.

The method may further include adding an MnO powder to the piezoelectric ceramic powder, after the adding of the CuO powder to the piezoelectric ceramic powder.

The electrode layer may be formed of a palladium (Pd)-silver (Ag) alloy.

The palladium (Pd)-silver (Ag) alloy may have a palladium content of 10 wt %.

The electrode layer may be formed of silver (Ag).

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a flowchart showing a method of manufacturing a ceramic composition for a piezoelectric actuator according to an exemplary embodiment of the present invention;

FIG. 2 is a cross-sectional view of a piezoelectric actuator according to an exemplary embodiment of the present invention; and

FIG. 3 is a graph showing piezoelectric characteristics of an inventive example.

### DETAILED DESCRIPTION OF THE PREFERRED EMBODIMENT

Hereinafter, preferred embodiments of the present invention will be described in detail with reference to the accompanying drawings. However, the exemplary embodiments of the present invention may be modified to have many different forms, and the scope of the invention should not be construed as being limited to the embodiments set forth herein. Rather, these embodiments are provided so that this disclosure will be thorough and complete, and will fully convey the concept of the invention to those skilled in the art.

A ceramic composition for a piezoelectric actuator, according to an embodiment of the present invention, may include: a piezoelectric ceramic powder represented by the compositional formula of (1-x)Pb(Zr_{(1-y)}Ti_{y})O₃-xPb(Zn_{1/3}Nb_{2/3})O₃, where x is 0.2 to 0.4 and y is 0.4 to 0.7; and CuO powder.

Herein, (1-x)Pb(Zr_{(1-y)}Ti_{y})O₃-xPb(Zn_{1/3}Nb_{2/3})O₃ is referred to as PZT-PZN. PZT-PZN is formed by adding a small amount of PZN to PZT, in order to improve the piezoelectric characteristics of PZT. The PZT-PZN piezoelectric ceramic powder may express various piezoelectric characteristics by adjusting a ratio of Zr to Ti.

The CuO powder, as a sintering additive, is further contained in PZT-PZN. When the CuO powder is added, the sintering temperature of the PZT-PZN ceramic composition may be lowered.

Also, the ceramic composition for a piezoelectric actuator may further include an MnO powder. The sintering temperature of the PZT-PZN ceramic composition in which the MnO powder is added becomes lowered.

The sintering temperature of the PZT-PZN ceramic composition can be lowered to 900° C. or less by adding the CuO powder and the MnO powder together.

The content of the CuO powder may be 0.01 to 5 mol %, and the content of the MnO powder may be 0.01 to 5 mol %. When the content of the CuO powder and the MnO powder exceeds 5mol %, the piezoelectric characteristics of the piezoelectric body can be deteriorated.

A method of manufacturing a ceramic composition for a piezoelectric actuator, according to an exemplary embodiment of the present invention, may include: preparing a ceramic mixture having a compositional formula of (1-x)Pb(Zr_{(1-y)}Ti_{y})O₃-xPb(Zn_{1/3}Nb_{2/3})O₃, by weighing raw materials such that x is 0.2 to 0.4 and y is 0.4 to 0.7 in the compositional formula; calcining the ceramic mixture to prepare a piezoelectric ceramic powder having a compositional formula of (1-x)Pb(Zr_{(1-y)}Ti_{y})O₃-xPb(Zn_{1/3}Nb_{2/3})O₃, where x is 0.2 to 0.4 and y is 0.4 to 0.7; and adding a CuO powder to the piezoelectric ceramic powder.

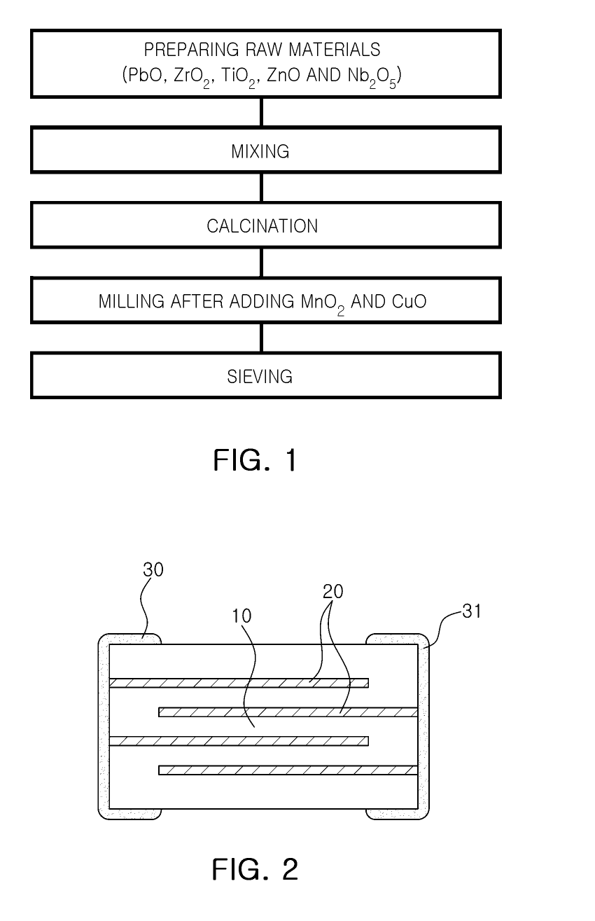

FIG. 1 shows a method of manufacturing a ceramic composition for a piezoelectric actuator.

The raw materials may be PbO, ZrO₂, TiO₂, ZnO and Nb₂O₅. These are the main raw materials constituting PZT-PZN.

The raw materials are inputted to a nylon container together with zirconia balls, and subjected to milling for 12 hours.

After the CuO powder is added to the piezoelectric ceramic powder, the MnO powder may be added to the piezoelectric ceramic powder.

After the ceramic mixture is calcined to prepare the PZT-PZN piezoelectric ceramic powder, the CuO powder may be further added as a sintering additive for lowering the sintering temperature.

In addition, the CuO powder and the MnO powder together may be added as a sintering additive for lowering the sintering temperature. The adding of the CuO powder and the MnO powder together may lower the sintering temperature.

After adding the sintering additive, the zirconia balls are inputted to the nylon container together with the sintering additive, followed by milling, so that the PZT-PZN piezoelectric ceramic powder and the sintering additive can be well mixed.

It is because that, when the sintering additive is uniformly dispersed among the PZT-PZN piezoelectric ceramic powders, the sintering additive for lowering the sintering temperature shows a function thereof itself in a case in which the PZT-PZN piezoelectric ceramic powder is sintered.

A piezoelectric actuator, according to an exemplary embodiment of the present invention, may include: one or more piezoelectric layers each including a ceramic composition containing a piezoelectric ceramic powder having a compositional formula of (1-x)Pb(Zr_{(1-y)}Ti_{y})O₃-xPb(Zn_{1/3}Nb_{2/3})O₃, where x is 0.2 to 0.4 and y is 0.4 to 0.7, and a CuO powder; and electrode layers each formed on at least one of an upper surface and a lower surface of the piezoelectric layer.

FIG. 2 shows a piezoelectric actuator according to an exemplary embodiment of the present invention.

Referring to FIG. 2, the piezoelectric actuator may include piezoelectric layers 10, electrode layers 20, and terminal electrodes 30 and 31.

The piezoelectric layer 10 may include a PZT-PZN piezoelectric ceramic composition as a main material, and further include a CuO powder as a sintering additive therein.

In addition, the piezoelectric layer 10 may include a CuO powder and an MnO powder together as a sintering additive therein.

A ceramic sheet may be arranged by mixing a PZT-PZN piezoelectric ceramic powder with a solvent, a binder, and the like, to prepare a slurry, and performing a doctor blade method or the like.

The electrode layer 20 is formed on one surface of the ceramic sheet.

The electrode layer 20 is formed of a palladium (Pd)-silver (Ag) alloy. The palladium (Pd) may be also used in high temperature sintering due to a high melting point thereof, but the palladium (pd) has a question of the high cost per unit.

In order to avoid high costs caused by using the palladium (Pd) as the electrode materials, the sintering additive such as CuO, MnO, or the like is added to lower the sintering temperature such that the palladium (Pd) does not need to be used.

In the palladium (Pd)-silver (Ag) alloy, the content of the palladium may be 10 wt %.

The lowered sintering temperature may allow the usage of palladium to be decreased, resulting in a lowered manufacturing costs.

The electrode layer 20 may be formed of silver (Ag).

When the sintering temperature is sufficiently lowered to 900° C. or less, only silver (Ag) maybe used as the electrode material.

The piezoelectric actuator may be manufactured by laminating ceramic sheets each having the electrode layer 20 thereon to form a ceramic sheet laminate body, and pressing, cutting, and sintering the ceramic sheet laminate body.

A method of manufacturing a piezoelectric actuator, according to another embodiment of the present invention, may include: preparing a ceramic mixture having a compositional formula of (1-x)Pb(Zr_{(1-y)}Ti_{y})O₃-xPb(Zn_{1/3}Nb_{2/3})O₃, by weighing raw materials such that x is 0.2 to 0.4 and y is 0.4 to 0.7 in the compositional formula; calcining the ceramic mixture to prepare a piezoelectric ceramic powder having a compositional formula of (1-x)Pb(Zr_{(1-y)}Ti_{y})O₃-xPb(Zn_{1/3}Nb_{2/3})O₃, where x is 0.2 to 0.4 and y is 0.4 to 0.7; adding a CuO powder to the piezoelectric ceramic powder; forming piezoelectric layers of the ceramic composition including the piezoelectric ceramic powder; forming electrode layers on at least one of an upper surface and a lower surface of each of the piezoelectric layers to form a laminate body; and firing the laminate body at a temperature of 950° C. or lower.

The raw materials may be PbO, ZrO₂, TiO₂, ZnO and Nb₂O₅.

The MnO powder may be further added to the piezoelectric ceramic powder, after the CuO powder is added to the piezoelectric ceramic powder.

The laminate body may be subjected to sintering at 950° C. or less. The low-temperature sintering may be implemented by adding the CuO powder and the MnO powder to the PZT-PZN piezoelectric ceramic powder.

The electrode layer may be formed of a palladium (Pd)-silver (Ag) alloy.

In the palladium (Pd)-silver (Ag) alloy, the content of the palladium may be 10 wt %.

The electrode layer may be formed of silver (Ag).

In the present exemplary embodiment, the matter with respect to the piezoelectric ceramic powder, the sintering additive, the piezoelectric layer, the inside electrode, and the like is as described above.

### INVENTIVE EXAMPLE

A case in which 1 mol %, 1.5 mol %, and 3 mol % of CuO was added is taken as an inventive example, and a case in which CuO was not added is taken as a comparative example.

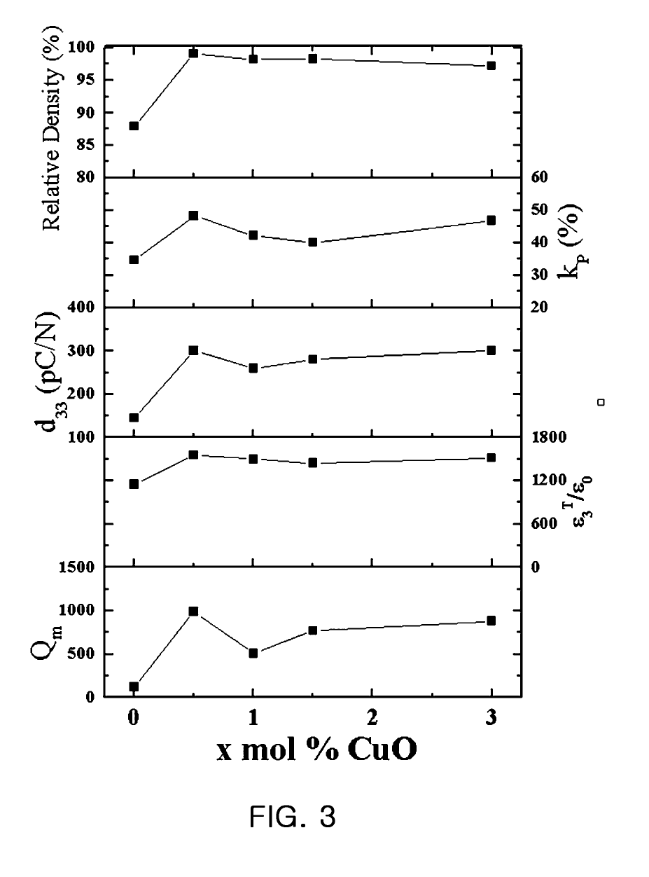

A change of piezoelectric characteristics according to the CuO content of a piezoelectric body sintered at a temperature of 900° C. is shown in FIG. 3.

Matters other than the CuO content are the same in the inventive example and the comparative example.

A piezoelectric constant d₃₃ means the extent of displacement when an electric field (V/m) is applied. The minute displacement may be adjusted as the piezoelectric constant is larger.

An electromechanical coupling coefficient, K, expresses a conversion efficiency between electric energy and mechanical energy. There are five kinds, that is, k₁₃, k₃₃, k₁₅, k_{z} and kₚ, of electromechanical coupling coefficient, according to vibration mode. kₚ is generally used for comparison of physical properties, and means a planar coupling factor.

A mechanical quality factor, Q, is a ratio of energy accumulated at the time of conversion between electric energy and mechanical energy, and in other words, a ratio of the average amount of energy stored to the amount of energy used, per cycle. The loss of energy is emitted, mostly, in a heat energy type. In general, when the value of mechanical quality factor is small, deterioration is accelerated.

Referring to FIG. 3, it shows that the inventive example is more excellent than the comparative example in all of relative density, electromechanical planar coupling factor (kp), piezoelectric constant (d₃₃), dielectric constant (d₃₃), and mechanical quality factor Qₘ. It shows that the inventive example has a more excellent sintering characteristic in view of having more excellent relative density, a more excellent conversion efficiency between electric energy and mechanical energy in view of having a larger electromechanical planar coupling factor, a more excellent dielectric characteristic in view of having a larger dielectric constant, and a longer lifespan due to less energy expended as heat, in view of having a larger mechanical quality factor than that of the comparative example.

In general, the density and the piezoelectric characteristics are proportional to each other.

As set forth above, according to an embodiment of the present invention, a ceramic composition for a piezoelectric actuator allowing for low-temperature sintering and a method of manufacturing the same, and a piezoelectric actuator manufactured by using the same can be implemented.

While the present invention has been shown and described in connection with the exemplary embodiments, it will be apparent to those in the art that modifications and variations can be made without departing from the spirit and scope of the invention as defined by the appended claims.

What is claimed is:

1. A ceramic composition for a piezoelectric actuator, comprising:
a piezoelectric ceramic powder having a compositional formula of (1-x)Pb(Zr_{(1-y)}Ti_{y})O₃-xPb(Zn_{1/3}Nb_{2/3})O₃, where x is 0.2 to 0.4 and y is 0.4 to 0.7; and
a CuO powder.

2. The ceramic composition for a piezoelectric actuator of claim 1, further comprising an MnO powder.

3. The ceramic composition for a piezoelectric actuator of claim 1, wherein the CuO powder has a content of 0.01 to 5 mol %.

4. The ceramic composition for a piezoelectric actuator of claim 2, wherein the MnO powder has a content of 0.01 to 5 mol %.

5. A method of manufacturing a ceramic composition for a piezoelectric actuator, the method comprising:
preparing a ceramic mixture having a compositional formula of (1-x)Pb(Zr_{(1-y)}Ti_{y})O₃-xPb(Zn_{1/3}Nb_{2/3})O₃, by weighing raw materials such that x is 0.2 to 0.4 and y is 0.4 to 0.7 in the compositional formula;
calcining the ceramic mixture to prepare a piezoelectric ceramic powder having a compositional formula of (1-x)Pb(Zr_{(1-y)}Ti_{y})O₃-xPb(Zn_{1/3}Nb_{2/3})O₃, where x is 0.2 to 0.4 and y is 0.4 to 0.7; and
adding a CuO powder to the piezoelectric ceramic powder.

6. The method of claim 5, wherein the raw materials are PbO, ZrO₂, TiO₂, ZnO and Nb₂O₅.

7. The method of claim 5, further comprising adding an MnO powder to the piezoelectric ceramic powder, after the adding of the CuO powder to the piezoelectric ceramic powder.

8. A piezoelectric actuator, comprising:
one or more piezoelectric layers each including a ceramic composition containing a piezoelectric ceramic powder having a compositional formula of (1-x)Pb(Zr_{(1-y)}Ti_{y})O₃-xPb(Zn_{1/3}Nb_{2/3})O₃, where x is 0.2 to 0.4 and y is 0.4 to 0.7, and a CuO powder; and
electrode layers each formed on at least one of an upper surface and a lower surface of the piezoelectric layer.

9. The piezoelectric actuator of claim 8, wherein the piezoelectric layer further includes an MnO powder.

10. The piezoelectric actuator of claim 8, wherein the electrode layer is formed of a palladium (Pd)-silver (Ag) alloy.

11. The piezoelectric actuator of claim 8, wherein the palladium (Pd)-silver (Ag) alloy has a palladium content of 10 wt %.

12. The piezoelectric actuator of claim 8, wherein the electrode layer is formed of silver (Ag).

13. A method of manufacturing a piezoelectric actuator, the method comprising:
preparing a ceramic mixture having a compositional formula of (1-x)Pb(Zr_{(1-y)}Ti_{y})O₃-xPb(Zn_{1/3}Nb_{2/3})O₃, by weighing raw materials such that x is 0.2 to 0.4 and y is 0.4 to 0.7 in the compositional formula;
calcining the ceramic mixture to prepare a piezoelectric ceramic powder having a compositional formula of (1-x)Pb(Zr_{(1-y)}Ti_{y})O₃-xPb(Zn_{1/3}Nb_{2/3})O₃, where x is 0.2 to 0.4 and y is 0.4 to 0.7;
adding a CuO powder to the piezoelectric ceramic powder;
forming piezoelectric layers of the ceramic composition including the piezoelectric ceramic powder;
forming electrode layers each on at least one of an upper surface and a lower surface of each of the piezoelectric layers to form a laminate body; and
firing the laminate body at a temperature of 950° C. or lower.

14. The method of 13, wherein the raw materials are PbO, ZrO₂, TiO₂, ZnO and Nb₂O₅.

15. The method of 13, further comprising adding an MnO powder to the piezoelectric ceramic powder, after the adding of the CuO powder to the piezoelectric ceramic powder.

16. The method of 13, wherein the electrode layer is formed of a palladium (Pd)-silver (Ag) alloy.

17. The method of 13, wherein the palladium (Pd)-silver (Ag) alloy has a palladium content of 10 wt %.

18. The method of 13, wherein the electrode layer is formed of silver (Ag).
